(19) United States
(12) Patent Application Publication
(10) Pub. No.: US 2018/0142369 A1
(43) Pub. Date: May 24, 2018

(54) ELECTRICALLY CONDUCTIVE SUBSTRATE

(71) Applicant: SUMITOMO METAL MINING CO., LTD., Tokyo (JP)

(72) Inventor: Yoshihide NISHIYAMA, Niihama-shi, Ehime (JP)

(73) Assignee: SUMITIMO METAL MINING CO., LTD.

(21) Appl. No.: 15/575,954

(22) PCT Filed: Jun. 22, 2016
(86) PCT No.: PCT/JP2016/068463

§ 371 Date: Nov. 21, 2017

(30) Foreign Application Priority Data
Jun. 26, 2015 (JP) 2015-129285

(51) Int. Cl. C25D 3/38; C25D 7/00; H01B 1/02

(52) U.S. Cl. CPC C25D 3/38; H03K 17/962; H01B 1/026; C25D 7/00

(57) ABSTRACT

There is provided an electrically conductive substrate including a transparent base, and a copper layer formed on at least one surface of the transparent base, wherein the copper layer is such that, when a film thickness of the copper layer is 0.5 μm, a surface resistance value is less than or equal to 0.07Ω/□.

### TECHNICAL FIELD

The present invention relates to an electrically conductive substrate.

### BACKGROUND ART

An electrostatic capacitive touch panel converts information about a location of an approaching object on a panel surface into an electric signal by detecting a change in electrostatic capacity caused by the object approaching the panel surface. As an electrically conductive substrate used for an electrostatic capacitive touch panel is installed on a surface of a display, a material of an electrically conductive layer of the electrically conductive substrate is required to have low reflectance and to be difficult to be visually recognized.

Accordingly, as a material of the electrically conductive layer used for the electrostatic capacitive touch panel, a material with low reflectance that is difficult to be visually recognized is used, and wiring is formed on a transparent substrate or a transparent film. For example, Patent Document 1 discloses a transparent electrically conductive film for a touch panel such that, as a transparent electrically conductive film, an ITO (indium oxide-tin) film is formed on a polymer film.

Recently, enlargement of a screen of a display with a touch panel has progressed, and accordingly enlargement of an area has been demanded for an electrically conductive substrate, such as a transparent electrically conductive film for a touch panel. However, a problem is that, as ITO has a high electric resistance value and causes deterioration of signals, it is not favorable for a large panel.

Accordingly, as disclosed in Patent Documents 2 and 3, for example, it has been studied to use metal foil, such as that of copper, as an electrically conductive layer, instead of an ITO film.

### PRIOR ART DOCUMENT

### Patent Document

Patent Document 1: Japanese Unexamined Patent Publication No. 2003-151358

Patent Document 2: Japanese Unexamined Patent Publication No. 2011-018194

Patent Document 3: Japanese Unexamined Patent Publication No. 2013-069261

### SUMMARY OF THE INVENTION

### Problem to be Solved by the Invention

Metal foil, such as that of copper, has, however, a metallic luster. Accordingly, when an electrically conductive substrate is provided with, as an electrically conductive layer, metal foil, such as that of copper, light is reflected on a surface, especially, on a side surface of the electrically conductive layer, so that visibility of a display may be lowered, depending on a thickness of the electrically conductive layer. Further, as the thickness of the electrically conductive layer is determined by a surface resistance value required for the electrically conductive substrate and a material forming the electrically conductive layer, it has been difficult, usually, to sufficiently reduce the thickness of the electrically conductive layer.

In view of the problem with the above-described related art, an object of an aspect of the present invention is to provide an electrically conductive substrate with which a surface resistance value can be sufficiently controlled, even if a thickness of a copper layer is small.

### Means for Solving Problem

According to an aspect of the present invention for solving the above-described problem, there is provided an electrically conductive substrate including a transparent base; and a copper layer that is formed on at least one surface of the transparent base, wherein the copper layer is such that, when a film thickness of the copper layer is 0.5 μm, a surface resistance value is less than or equal to 0.07Ω/□.

### Advantage of The Invention

According to an aspect of the present invention, an electrically conductive substrate can be provided with which a surface resistance value can be sufficiently controlled, even if a thickness of a copper layer is small.

### BRIEF DESCRIPTION OF THE DRAWINGS

FIG. 1A is a cross-sectional view of an electrically conductive substrate according to an embodiment of the present invention;

FIG. 1B is a cross-sectional view of the electrically conductive substrate according to the embodiment of the present invention;

FIG. 2A is a diagram illustrating a configuration of a patterned electrically conductive substrate according to the embodiment of the present invention;

FIG. 2B is a cross-sectional view along an A-A′ line of FIG. 2A;

FIG. 3A is a diagram illustrating a configuration of a laminated electrically conductive substrate provided with mesh-shaped wiring according to the embodiment of the present invention;

FIG. 3B is a cross-sectional view along a B-B′ line of FIG. 3A;

FIG. 4 is a cross-sectional view of an electrically conductive substrate provided with mesh-shaped wiring according to the embodiment of the present invention; and

FIG. 5 is a diagram of relation between a thickness of a copper layer and a surface resistance value in preliminary tests of examples and a reference example.

### EMBODIMENTS OF THE INVENTION

In the following, an embodiment of an electrically conductive substrate according to the present invention is described.

The electrically conductive substrate according to the embodiment includes a transparent base and a copper layer formed on at least one surface of the transparent base. Then, the copper layer may be adjusted so that, when a film thickness of the copper layer is 0.5 μm, a surface resistance value is less than or equal to 0.07Ω/□.

Note that the electrically conductive substrate according to the embodiment includes a substrate prior to patterning a copper layer, etc., such that the copper layer is provided on a surface of a transparent base; and a substrate in which a copper layer, etc., is patterned, i.e., a wiring substrate. After the copper layer is patterned, the transparent base includes a region that is not covered with the copper layer, etc., and, hence, can transmit light, so that the electrically conductive substrate becomes a transparent electrically conductive substrate.

First, components included in the electrically conductive substrate are described below.

The transparent base is not particularly limited. A resin substrate that transmits visible light (resin film), or a glass substrate, etc., may preferably be used.

As a material of a resin substrate that transmits visible light, the following resins can preferably be used: polyamide series resin, polyethylene terephthalate series resin, polyethylene naphthalate series resin, cycloolefin series resin, polyimide series resin, and polycarbonate series resin. In particular, as a material of a resin substrate that transmits visible light, PET (polyethylene terephthalate), COP (cycloolefin polymer), PEN (polyethylene naphthalate), polyamide, polyimide, polycarbonate, etc., can more preferably be used.

A thickness of the transparent base is not particularly limited, and it can be freely selected depending on strength, electrostatic capacity, light transmittance, etc., required for the electrically conductive substrate. The thickness of the transparent base may, for example, be adjusted to be greater than or equal to 10 μm and less than or equal to 200 μm. Especially, when it is used for a touch panel, the thickness of the transparent base may preferably be adjusted to be greater than or equal to 20 μm and less than or equal to 120 μm, more preferably be adjusted to be greater than or equal to 20 μm and less than or equal to 100 μm. When it is used for a touch panel, and, for example, when it is required to reduce the thickness of the entire display, the thickness of the transparent base may preferably be greater than or equal to 20 μm and less than or equal to 50 μm.

It is preferable that total light transmittance of the transparent base be high. For example, the total light transmittance is preferably greater than or equal to 30%, more preferably greater than or equal to 60%. By adjusting the total light transmittance of the transparent base to be within the above-described range, for example, when it is used for a touch panel, visibility of a display can be sufficiently ensured.

Note that the total light transmittance of the transparent base can be evaluated by a method specified in JIS K 7361-1.

The transparent base may be provided with a first principal plane and a second principal plane. Note that the principal plane used herein refers to a flat part with a largest area among the planes included in the transparent base. Further, the first principal plane and the second principal plane denote surfaces arranged to face each other in the single transparent base. Namely, the second principal plane denotes a plane located at a side opposite to the first principal plane.

Next, the copper layer is described.

When the film thickness is 0.5 μm, the surface resistance value of the copper layer is preferably be less than or equal to 0.07Ω/□, more preferably less than or equal to 0.05Ω/□.

As already described, when metal foil is used as an electrically conductive layer of the electrically conductive substrate, and when the electrically conductive layer is arranged on a screen of a display, such as a touch panel, visibility of a display may be lowered, depending on the thickness of the electrically conductive layer, due to reflection of light on the surface of the electrically conductive layer, especially on the side surface of the electrically conductive layer because the electrically conductive layer is provided with a metallic luster.

However, a thickness of the electrically conductive layer is selected by the absolute value, etc., of the surface resistance value required for the electrically conductive substrate and a material forming the electrically conductive layer, so that it is difficult to reduce the thickness of the electrically conductive layer in which usual metal foil with a large surface resistance value is used.

Accordingly, as for the electrically conductive substrate according to the embodiment, an electrically conductive substrate can be obtained with which the surface resistance value can be sufficiently controlled, even if the thickness of the copper layer is small, by using a copper layer such that, when the film thickness is 0.5 μm, the surface resistance value is less than or equal to 0.07Ω/□. The copper layer can function as the electrically conductive layer.

Note that, “the copper layer such that, when the film thickness is 0.5 μm, the surface resistance value is less than or equal to 0.07Ω/□,” which is described here, is not intended to limit the film thickness of the copper layer to 0.5 μm. It implies that, when the film of the copper layer with the film thickness of 0.5 μm is formed under a condition that is the same as the condition for forming a film of the copper layer included in the electrically conductive substrate, the surface resistance value is less than or equal to 0.07Ω/□.

The method of forming the copper layer on the transparent base is not particularly limited: however, in order not to reduce light transmittance, an adhesive may not preferably be placed between the transparent base and the copper layer. Namely, the copper layer may preferably be directly formed on at least one surface of the transparent base. Note that, when an adhesive layer is placed between the transparent base and the copper layer as described below, it may preferably be directly formed on an upper surface of the adhesive layer.

The copper layer may be obtained, for example, by forming, by a dry plating method, a copper thin film layer on the transparent base as the copper layer. Consequently, the copper layer can be directly formed on the transparent base without placing an adhesive. Note that, as the dry plating method, for example, a sputtering method, a vapor deposition method, an ion plating method, etc., may preferably be used, which are described in detail below.

When the film thickness of the copper layer is to be further increased, by forming a copper plating layer by a wet plating method using a copper thin film layer as a power feeding layer, a copper layer provided with the copper thin film layer and the copper plating layer can be obtained. As the copper layer is provided with the copper thin film layer and the copper plating layer, in this case, the copper layer can also be directly formed on the transparent base without placing an adhesive.

The copper layer can be provided with the copper thin film layer because the copper layer is directly formed on the upper surface of the transparent base, as described above. Further, the copper layer may be provided with both the copper thin film layer and the copper plating layer. However, from a perspective of reducing, especially, the surface resistance value of the copper layer, the copper layer may preferably be provided with the copper thin film layer and the copper plating layer.

The thickness of the copper layer is not particularly limited, and it can be freely selected depending on, when the copper layer is used as wiring, an absolute value of an electric current supplied to the wiring and width, etc., of the wiring.

However, when the thickness of the copper layer is increased, side etching tends to occur because it takes time to perform etching to form a wiring pattern, so that a problem may arise, such as it becomes difficult to form a thin line. For this reason, the thickness of the copper layer may preferably be less than or equal to 5 μm, more preferably less than or equal to 3 μm.

In particular, in the electrically conductive substrate according to the embodiment, the surface resistance value of the electrically conductive substrate can be sufficiently reduced even if the thickness of the copper layer is small. Accordingly, by reducing the thickness of the copper layer, reflection of light on the surface, especially on the side surface, of the copper layer can be suppressed, and deterioration of visibility of the display can be suppressed even if it is used for applications in which it is to be placed on a screen, etc., of a display, such as a touch panel. Accordingly, in the electrically conductive substrate according to the embodiment, the thickness of the copper layer may be more preferably less than or equal to 1.0 μm, particularly preferably less than or equal to 0.5 μm.

Further, the lower limit value of the thickness of the copper layer is not particularly limited. However, from a perspective of reducing the resistance value of the electrically conductive substrate so as to allow a sufficient electric current to be supplied, for example, the thickness of the copper layer may preferably be greater than or equal to 50 nm, more preferably greater than or equal to 60 nm, and further more preferably greater than or equal to 150 nm.

Note that, when the copper layer is provided with the copper thin film layer and the copper plating layer, as described above, the total of the thickness of the copper thin film layer and the thickness of the copper plating layer may preferably be within the above-described range.

The thickness of the copper thin film layer is not particularly limited when the copper layer is formed of the copper thin film layer, or when the copper layer is formed of the copper thin film layer and the copper plating layer; however, it may preferably be greater than or equal to 50 nm and less than or equal to 500 nm, for example.

As described below, by patterning the copper layer, for example, into a desired wiring pattern, the copper layer can be used as wiring. Then, as the surface resistance value can be reduced for the copper layer compared to that of the ITO film, which has been used, usually, as the transparent electrically conductive film, by providing the copper layer, the surface resistance value of the electrically conductive substrate can be reduced.

A method of forming a film of the copper layer such that, when the film thickness of the copper layer is 0.5 μm, the surface resistance value is less than or equal to 0.07Ω/□ is not particularly limited; however, for example, the copper layer preferably includes a copper plating layer formed by a wet process, and the copper plating layer is preferably formed using a single plating layer. Namely, the copper layer preferably includes a copper plating layer (wet copper plating layer) and the copper plating layer is preferably a single plating tank.

According to the study by the inventors of the present invention, in the copper plating layer, crystals of copper gradually grow within the copper plating layer immediately after the film is formed and become large. Then, as the size of the crystals of copper within the copper plating layer becomes large, the surface resistance value of the copper layer can be particularly lowered.

However, during formation of the film of the copper plating layer by the wet process, if two or more plating tanks are arranged in series along the conveying direction of the substrate, a copper plating film is formed in each plating tank, and the copper plating layer is formed by laminating these, a layer of fine crystals may be formed between the copper plating layers. Then, after forming the copper plating films, growth of copper crystals progresses in each copper plating layer; however, it is considered that, if the layer of fine crystals is formed between the copper plating films, crystal growth beyond the copper plating films is inhibited. Consequently, when the film of the copper plating layer is formed using a plating tank with a plurality of tanks, growth of the copper crystals is not sufficiently progressed.

In contrast, when the film of the copper plating layer is formed by using the single plating tank, as described above, the copper plating layer is formed of a single layer and growth of the copper crystals progresses over the entire layer. Accordingly, after forming the film, growth of the copper crystals sufficiently progresses, and the surface resistance value of the copper layer can be lowered. Consequently, by forming a film of a copper plating layer by using a single plating tank, a surface resistance value of the copper layer can be particularly lowered.

Note that the wet film forming method for forming the film of the copper plating layer may any one of an electroplating method and an electroless plating method; however, the electroplating method is preferable.

As another method of forming a film of the copper layer in which the surface resistance value of the copper layer is within the above-described predetermined range, a method is considered such that the copper layer includes a film of a copper plating layer formed by the electroplating method, and, during formation of the film of the copper plating layer, the film is formed by using an additive including a diallyldimethylammonium chloride polymer. Namely, the copper plating layer may preferably include a component derived from the diallyldimethylammonium chloride polymer included in the plating solution.

When the film of the copper plating layer is formed by the electroplating method, which is a type of a wet method, the plating solution is not particularly limited, and various types of copper plating solutions may be used. However, according to the study by the inventors of the present invention, by adding, as the additive, the diallyldimethylammonium chloride polymer to the copper plating solution, crystal growth of copper included in the formed film of the copper plating layer can be progressed. Then, crystal growth of copper within the copper plating layer is progressed and the size of the crystals of copper increases. As a result, the surface resistance value of the copper layer can be lowered.

Specifically, according to the study by the inventors of the present invention, it is more preferable that the copper layer may include the film of the copper plating layer formed by the electroplating method, and that a single plating tank be used for the copper plating layer and the diallyldimethylammonium chloride polymer be used as the additive for the copper plating solution. The reason is that crystals of copper in the copper plating layer can particularly be grown due to synergistic working between the effect of forming the copper plating layer by using the single plating tank and the use of the diallyldimethylammonium chloride polymer as the additive for the copper plating solution. Then, by the growth of the crystals of copper in the copper plating layer, the surface resistance values of the copper plating layer and the electrically conductive substrate can be lowered.

When the diallyldimethylammonium chloride polymer is added to the copper plating solution as the additive, the addition amount is not particularly limited and it can be freely selected. For example, it can be added so that the addition amount of the diallyldimethylammonium chloride polymer in the copper plating solution is greater than or equal to 5 mg/L and less than or equal to 40 mg/L.

The molecular weight of the diallyldimethylammonium chloride polymer may preferably be in a range from 3500 to 4500. The reason is that, when' the molecular weight is less than 3500, copper crystal growth in the formed film of the copper layer may not be progressed sufficiently, and when it exceeds 4500, it may not sufficiently contribute to the growth of the copper crystals.

The diallyldimethylammonium polymer may be a single polymer; however, it is particularly desirable for promoting crystal growth of copper to use a diallyldimethylammonium-SO₂ copolymer, as the diallyldimethylammonium polymer. Namely, it is preferable that the copper plating layer includes a component derived from the diallyldimethylammonium-SO₂ copolymer included in the plating solution.

The electrically conductive substrate according to the embodiment may be provided with any layer other than the transparent base and the copper layer. For example, a blackening layer and an adhesive layer may be provided. The blackening layer and the adhesive layer are described below.

The blackening layer is described.

The blackening layer may be formed on at least one surface of the transparent base. Specifically, for example, it can be formed on the outer surface side of the electrically conductive substrate compared with the copper layer. By providing the blackening layer, reflection of the light on the surface of the copper layer on which the blackening layer is formed can further be suppressed.

The material of the blackening layer is not particularly limited, and any material can preferably be used as long as reflection of light on the surface of the copper layer can be suppressed.

The blackening layer may preferably include, for example, one or more metals selected from Ni, Zn, Mo, Ta, Ti, V, Cr, Fe, Co, W, Cu, Sn, and Mn. Additionally, the blackening layer may further include one ore more elements selected from carbon, oxygen, hydrogen, and nitrogen.

Note that the blackening layer may preferably include a metal alloy that includes two or more metals selected from Ni, Zn, Mo, Ta, Ti, V, Cr, Fe, Co, W, Cu, Sn, and Mn. In this case, the blackening layer may also include one or more elements selected from carbon, oxygen, hydrogen, and nitrogen. At this time, as the metal alloy that includes two or more metals selected from Ni, Zn, Mo, Ta, Ti, V, Cr, Fe, Co, W, Cu, Sn, and Mn, a Ci—Ti—Fe alloy, a Cu—Ni—Fe allow, an Ni—Cu alloy, an Ni—Zn alloy, an Ni—Ti alloy, an Ni—W alloy, an Ni—Cr alloy, and an Ni—Cu—Cr alloy may preferably be used.

The method of forming the blackening layer is not particularly limited and it can be formed by any method; for example, its film can be formed by a dry method or a wet method.

When the film of the blackening layer is formed by the dry method, the specific method is not particularly limited; however, for example, a dry plating method, such as a sputtering method, an ion plating method, an evaporation method, etc., may preferably be used. When the film of the blackening layer is formed by the dry method, the sputtering method is preferably used because the film thickness can be easily controlled. Note that, as described above, one or more elements selected from carbon, oxygen, hydrogen, and nitrogen can be added to the blackening layer, and, in this case, a reactive sputtering method may more preferably be used.

When the film of the blackening layer is formed by the reactive sputtering method, as the target, a target including the types of the metals forming the blackening layer can be used. When the blackening layer includes an alloy, for each of the types of the metals included in the blackening layer, a target may be used to form the alloy on the surface of a film formation target, such as a substrate, or a target may be used in which the metals included in the blackening layer are alloyed in advance.

Further, when the blackening layer is to include one or more elements selected from carbon, oxygen, hydrogen, and nitrogen, these can be added to inside the blackening layer by adding these to the atmosphere for forming the film of the blackening layer. For example, when carbon is to be added to the blackening layer, carbon monoxide gas and/or carbon dioxide gas may be added to the atmosphere for performing sputtering; when oxygen is to be added, oxygen gas may be added to the atmosphere for performing sputtering; when hydrogen is to be added, hydrogen gas and/or water may be added to the atmosphere for performing sputtering; and when nitrogen is to be added, nitrogen gas may be added to the atmosphere for performing sputtering. By adding these gases to an inert gas for forming the film of the blackening layer, one or more elements selected from carbon, oxygen, hydrogen, and nitrogen can be added to inside the blackening layer. Note that, as the inert gas, argon can preferably be used.

When the film of the blackening layer is to be formed by the wet method, for example, the film can be formed by the electroplating method using a plating solution corresponding to a material of the blackening layer.

The thickness of the blackening layer is not particularly limited; however, for example, it may preferably be greater than or equal to 15 nm, and more preferably greater than or equal to 25 nm. When the thickness of the blackening layer is small, reflection of light on the surface of the copper layer may not be sufficiently controlled. Accordingly, it is preferable to adopt a configuration, as described above, that the thickness of the blackening layer is greater than or equal to 15 nm, so that the reflection of the light on the surface of the copper layer can be sufficiently controlled.

The upper limit value of the thickness of the blackening layer is not particularly limited; however, even if it is made thicker than necessary, the time required for film formation and the time required for etching to form the wiring become long, which may result in an increase in cost. Consequently, the thickness of the blackening layer may preferably be less than or equal to 70 nm, more preferably less than or equal to 50 nm.

In the electrically conductive substrate according to the embodiment, by placing the blackening layer, the reflection of the light on the surface of the copper layer can further be controlled, as described above. Consequently, when it is used, for example, for an application, such as a touch panel, deterioration of visibility of the display can particularly be suppressed.

An example of a configuration of an adhesive layer is described.

As already described, the copper layer can be formed on the transparent base; however, when the copper layer is directly formed on the transparent base, adhesion between the transparent base and the copper layer may not be sufficient.

Thus, in the electrically conductive substrate according to the embodiment, in order to enhance the adhesion between the transparent base and the copper layer, an adhesive layer may be placed on the transparent base.

By placing an adhesive layer between the transparent base and the copper layer, the adhesion between the transparent base and the copper layer can be enhanced, and peeling off of the copper layer from the transparent base can be suppressed.

Additionally, the adhesive layer may be caused to function as a blackening layer. As a result, reflection of light on the copper layer caused by light from the lower surface side of the copper layer, i.e., from the side of the transparent base, can also be suppressed.

The material forming the adhesive layer is not particularly limited. It can be freely selected depending on the degree of adhesion between the transparent base and the copper layer and the degree of required suppression of reflection of light on the surface of the copper layer, and the degree of stability with respect to the environment (e.g., humidity and temperature) in which the electrically conductive substrate is used.

For example, the adhesive layer may preferably include one or more metals selected from Ni, Zn, Mo, Ta, Ti, V, Cr, Fe, Co, W, Cu, Sn, and Mn. The adhesive layer may further include one or more elements selected from carbon, oxygen, hydrogen, and nitrogen.

Note that the adhesive layer may include an alloy that includes two or more metals selected from Ni, Zn, Mo, Ta, Ti, V, Cr, Fe, Co, W, Cu, Sn, and Mn. In this case, the adhesive layer may also include one or more elements selected from carbon, oxygen, hydrogen, and nitrogen. At this time, as the alloy including two or more metals selected from Ni, Zn, Mo, Ta, Ti, V, Cr, Fe, Co, W, Cu, Sn, and Mn, a Ci—Ti—Fe alloy, a Cu—Ni—Fe alloy, an Ni—Cu alloy, an Ni—Zn alloy, an Ni—Ti alloy, an Ni—W alloy, an Ni—Cr alloy, or an Ni—Cu—Cr alloy may preferably be used.

The film formation method of the adhesive layer is not particularly limited; however, the film may preferably be formed by a dry plating method. As the dry plating method, for example, a sputtering method, an ion plating method, a vapor deposition method, etc., may preferably be used. When the film of the adhesive layer is formed by the dry method, the sputtering method may more preferably used because the film thickness can be easily controlled. Note that, as described above, one or more elements selected from carbon, oxygen, hydrogen, and nitrogen may be added to the adhesive layer, and, in this case, a reactive sputtering method can more preferably be used.

When the adhesive layer is to include one or more elements selected from carbon, oxygen, hydrogen, and nitrogen, these can be added to inside the adhesive layer by adding a gas including the one or more elements selected from carbon, oxygen, hydrogen, and nitrogen to the atmosphere for forming the film of the adhesive layer. For example, when carbon is to be added to the adhesive layer, carbon monoxide gas and/or carbon dioxide gas may be added to the atmosphere for performing the dry plating; when oxygen is to be added, oxygen gas may be added to the atmosphere for performing the dry plating; when hydrogen is to be added, hydrogen gas and/or water may be added to the atmosphere for performing the dry plating; and when nitrogen is to be added, nitrogen gas may be added to the atmosphere for performing the dry plating.

The gas including the one or more elements selected from carbon, oxygen, hydrogen, and nitrogen may preferably be added to an inert gas to be used as an atmosphere gas during the dry plating. The inert gas is not particularly limited; however, for example, argon can preferably be used.

As described above, by forming the film of the adhesive layer by the dry plating method, the adhesion between the transparent base and the adhesive layer can be enhanced. Further, as the adhesive layer may include, for example, a metal, as a main component, it has high adhesion to the copper layer. Consequently, by placing the adhesive layer between the transparent base and the copper layer, peeling off of the copper layer can be suppressed.

The thickness of the adhesive layer is not particularly limited; however, for example, it may preferably be greater than or equal to 3 nm and less than or equal to 50 nm, more preferably greater than or equal to 3 nm and less than or equal to 35 nm, and further more preferably greater than or equal to 3 nm and less than or equal to 33 nm.

When the adhesive layer is also caused to function as the blackening layer, i.e., when reflection of light on the copper layer is to be suppressed by the adhesive layer, the thickness of the adhesive layer may preferably be greater than or equal to 3 nm, as described above.

The upper limit value of the thickness of the adhesive layer is not particularly limited; however, even if it is made thicker than necessary, the time required for film formation and the time required for etching to form the wiring become long, which may result in an increase in cost. Consequently, as described above, the thickness of the adhesive layer may preferably be less than or equal to 50 nm, more preferably less than or equal to 35 nm, and furthermore preferably less than or equal to 33 nm.

Next, an example of a configuration of the electrically conductive substrate is described.

The electrically conductive substrate according to the embodiment may be provided with the transparent base and the copper layer, and it may be configured such that the copper layer is placed on at least one surface of the transparent base.

Furthermore, when the above-described adhesive layer and the blackening layer are to be placed, a configuration may be adopted, for example, such that the adhesive layer, the copper layer, and the blackening layer are laminated, in this order, on at least one surface of the transparent base. Note that only one of the adhesive layer and the blackening layer may be placed.

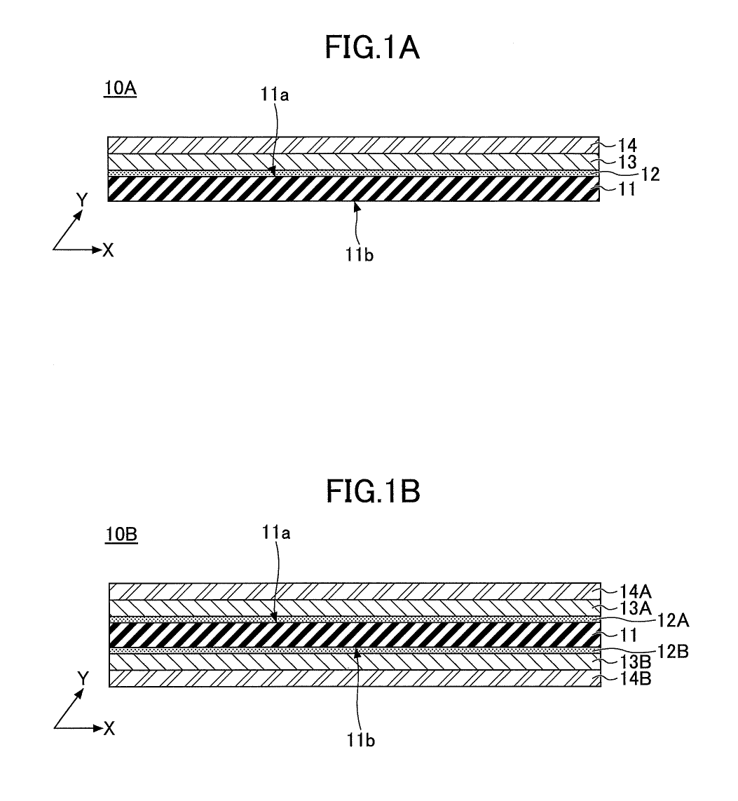

Examples of specific configurations are described below using FIG. 1A and FIG. 1B. Each of FIG. 1A and FIG. 1B illustrates an example in which an adhesive layer and a blackening layer are provided, in addition to the copper layer, in the electrically conductive substrate according to the embodiment, and illustrates an example of a cross-sectional view on a plane parallel to a direction in which the transparent base, the adhesive layer, the copper layer, and the blackening layer are laminated. Note that, as already described, one of or both of the adhesive layer and the blackening layer may not be provided.

For example, as an electrically conductive substrate 10A illustrated in FIG. 1A, a structure may be adopted such that on a side of a first principal plane 11a of a transparent base 11, an adhesive layer 12, a copper layer 13, and a blackening layer 14 are laminated one by one in this order. Further, as an electrically conductive substrate 10B illustrated in FIG. 1B, on a side of the first principal plane 11a of the transparent base 11, an adhesive layer 12A, a copper layer 13A, and a blackening layer 14A may be laminated one by one in this order; and on a side of a second principal plane 11b of the transparent base 11, an adhesive layer 12B, a copper layer 13B, and a blackening layer 14B may be laminated one by one in this order.

As illustrated in FIG. 1A and FIG. 1B, by placing the blackening layer 14 (14A, 14B) on an upper surface of the copper layer 13 (13A, 13B), reflection of light from the side of the upper surface of the copper layer 13 (13A, 13B) can be suppressed.

Further, by providing the adhesive layer 12 (12A, 12B), adhesion between the transparent base 11 and the copper layer 13 (13A, 13B) may be enhanced, and, in particular, peeling off of the copper layer 13 (13A, 13B) from the transparent base 11 can be suppressed. Furthermore, it is preferable to provide the adhesive layer 12 (12A, 12B) because, for the surface of the copper layer 13 (13A, 13B) on which the blackening layer 14 (14A, 14B) is not provided, reflection of light can be suppressed.

The electrically conductive substrate according to the embodiment is described so far. The electrically conductive substrate according to the embodiment may be used as a single plate of the electrically conductive substrate; however, it can be used to form a laminated electrically conductive substrate in which a plurality of plates of the electrically conductive substrates according to embodiment is laminated.

For each of the electrically conductive substrate according to the embodiment and the laminated electrically conductive substrate obtained by laminating the electrically conductive substrates, the copper layer included in the electrically conductive substrate may be patterned depending on an application. Further, when the blackening layer and/or the adhesive layer are provided, these layers may also be patterned, similar to the copper layer.

In particular, when it is used for an application of a touch panel, the electrically conductive substrate or the laminated electrically conductive substrate may preferably be provided with a mesh-shaped wiring.

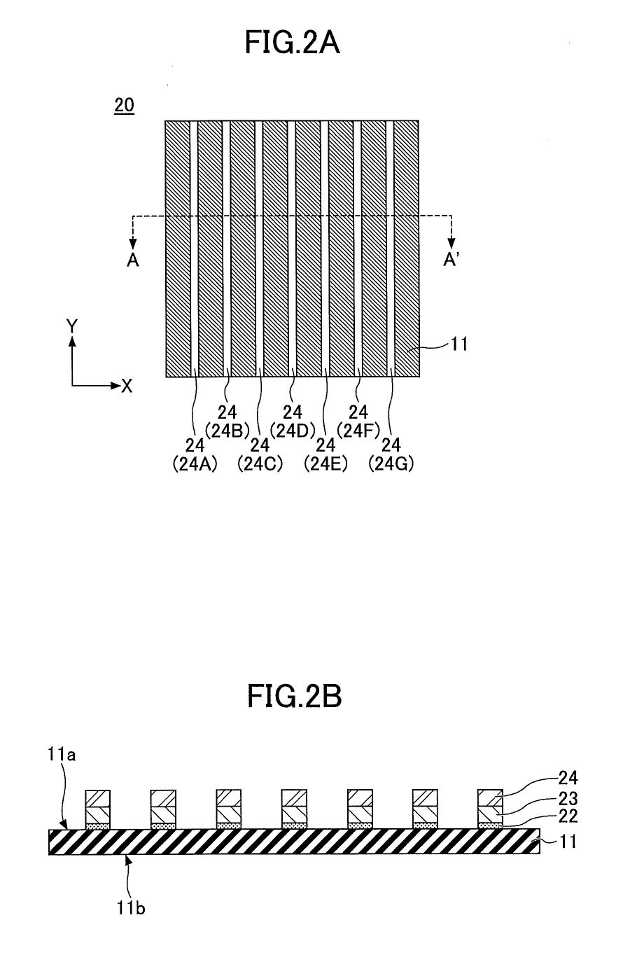

Here, examples of configurations of pattern shapes the copper layer formed in the electrically conductive substrate prior to lamination and the optionally provided adhesive layer and blackening layer are described using FIG. 2A and FIG. 2B, while exemplifying a case where a laminated electrically conductive substrate provided with a mesh-shaped wiring is formed by laminating two plates of electrically conductive substrates. Note that the patterned copper layer may function as a wiring.

FIG. 2A is a diagram obtained by viewing, from a side of an upper surface of the electrically conductive substrate 20, namely, in a direction perpendicular to the principal plane of the transparent base 11, one electrically conductive substrate of the two plates of the electrically conductive substrates forming the laminated electrically conductive substrate provided with the mesh-shaped wiring. Further, FIG. 2B illustrates a cross-sectional view along the A-A′ line of FIG. 2A.

As illustrated in FIG. 2A and FIG. 2B, in the electrically conductive substrate 20, the adhesive layer 22, the copper layer 23, and the blackening layer 24, which are patterned, on the transparent base 11 have the same cross-sectional shapes on a surface parallel to the principal planes 11a and 11b of the transparent base 11. For example, the patterned blackening layer 24 is provided with a plurality of line-shaped patterns illustrated in FIG. 2A (the blackening layer patterns 24A through 24G), and the line-shaped patterns can be arranged such that they are parallel to the Y-axis in the figure and separated from each other in the X-axis direction in the figure. At this time, when the transparent base 11 has a rectangular shape as illustrated in FIG. 2A, the patterns of the blackening layer (the blackening layer patterns 24A through 24G) can be arranged to be parallel to one edge of the transparent base 11.

Note that, as described above, the copper layer 23 and the adhesive layer 22 are patterned similar to the patterned blackening layer 23. Each of them is provided with a plurality of line-shaped patterns (copper layer patterns, adhesive layer patterns), and the patterns can be arranged in parallel while being separated from each other. As a result, between the patterns, the first principal plane 11a of the transparent base 11 is exposed.

The method of forming the patterns of the patterned adhesive layer 22, the patterned copper layer 23, and the patterned blackening layer 24 illustrated in FIG. 2A and FIG. 2B is not particularly limited. For example, the patterns can be formed by etching while placing a mask having a shape corresponding to that of the patterns to be formed on the blackening layer, after forming the blackening layer. The etchant to be used is not particularly limited, and it can be freely selected depending on a material forming the layer to be etched. For example, the etchant may be changed for each layer, or the copper layer, the blackening layer, and the adhesive layer may be simultaneously etched by the same etchant. Note that, when no blackening layer is provided, patterning can be similarly performed by placing the mask on the copper layer, after forming the copper layer.

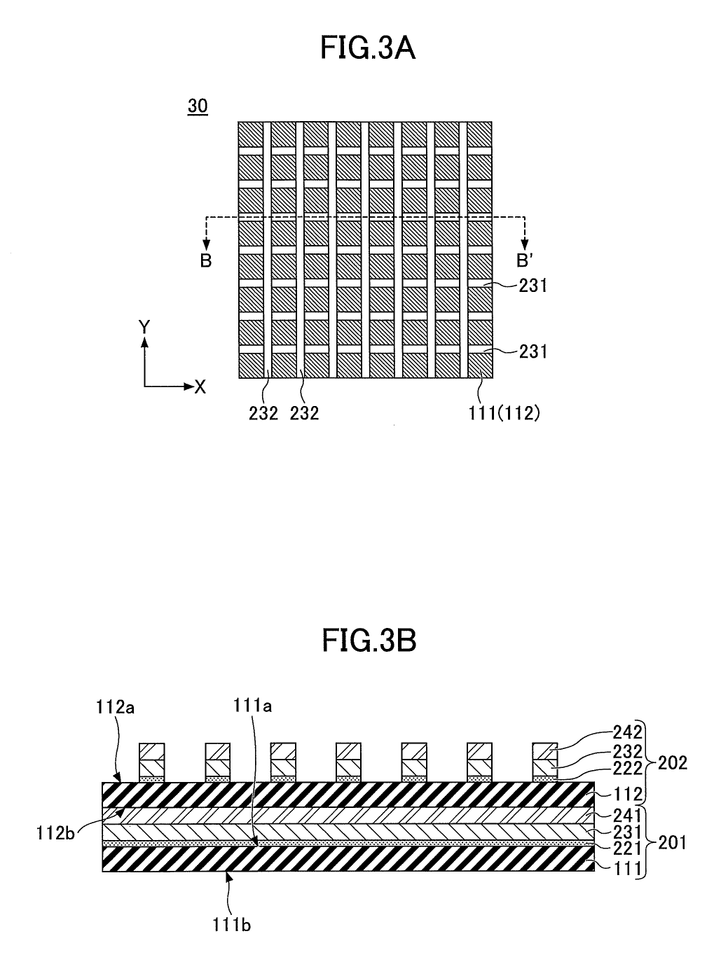

Then, by laminating two plates of electrically conductive substrates in which the copper layers are patterned, the laminated electrically conductive substrate can be formed. Note that, when, in addition to the copper layer, the adhesive layer and the blackening layer are formed, the adhesive layer and the blackening layer may preferably be patterned. The laminated electrically conductive substrate is described by using FIG. 3A and FIG. 3B. FIG. 3A is a diagram obtained by viewing the laminated electrically conductive substrate 30 from a side of an upper surface, namely, from the side of the upper surface along a direction in which the two plates of the electrically conductive substrates are laminated; and FIG. 3B illustrates a cross-sectional view along the B-B′ line of FIG. 3A.

As illustrated in FIG. 3B, the laminated electrically conductive substrate 30 is obtained by laminating an electrically conductive substrate 201 and an electrically conductive substrate 202. Note that, in each of the electrically conductive substrates 201 and 202, the adhesive layer 221 (222), the copper layer 231 (232), and the blackening layer 241 (242), which are patterned, are laminated on the first principal plane 111a (112a) of the transparent base 111 (112). The adhesive layer 221 (222), the copper layer 231 (232), and the blackening layer 241 (242) of each of the electrically conductive substrates 201 and 202 are patterned to have a plurality of line-shaped patterns, similar to the above-described electrically conductive substrate 20.

Then, the first principal plane 111a of the transparent base 111 of the one electrically conductive substrate 201 is laminated to face the second principal plane 112b of the transparent base 112 of the other electrically conductive substrate 202.

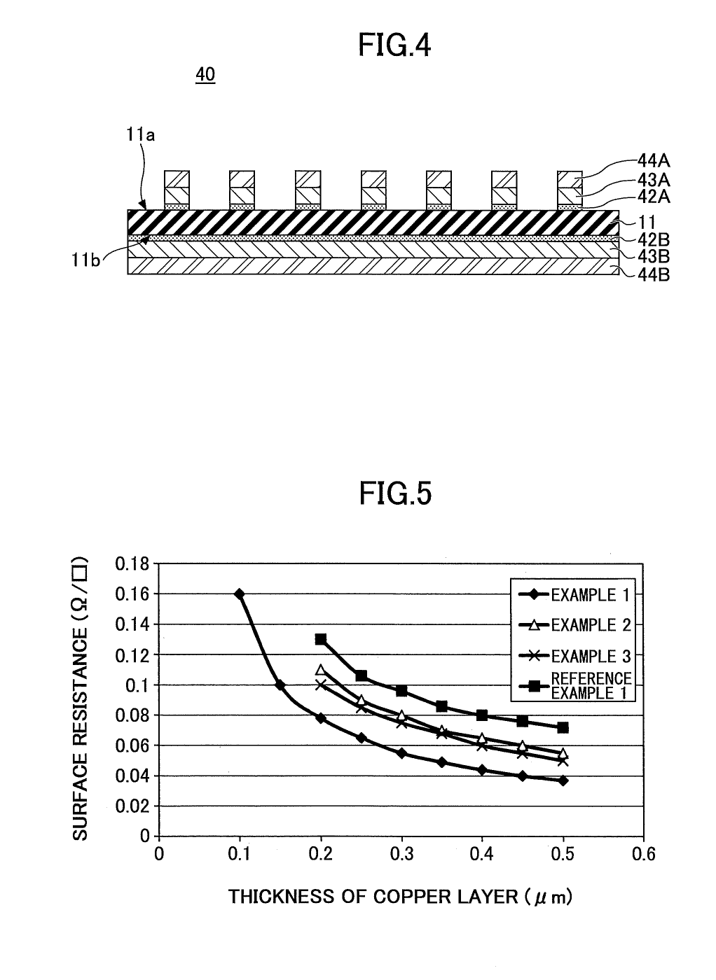

Note that, the one electrically conductive substrate 201 may be turned upside-down, and they may be laminated so that the second principal plane 111b of the transparent base 111 of the one electrically conductive substrate 201 faces the second principal plane 112b of the transparent base 112 of the other electrically conductive substrate 202. In this case, the arrangement is the same as that of FIG. 4, which is described below.

When the two plates of the electrically conductive substrates are to be laminated, as illustrated in FIG. 3A and FIG. 3B, they can be laminated so that the patterned copper layer 231 of the one electrically conductive substrate 201 intersects the patterned copper layer 232 of the other electrically conductive substrate 202. Specifically, for example, in FIG. 3A, the patterned copper layer 231 of the one electrically conductive substrate 201 may be arranged so that the longitudinal direction of the pattern is parallel to the X-axis direction in the figure. Then, the patterned copper layer 232 of the other electrically conductive substrate 202 may be arranged so that the longitudinal direction of the pattern is parallel to the Y-axis direction in the figure.

Note that, as FIG. 3A is a diagram obtained by viewing the laminated electrically conductive substrate 30 in the direction of the lamination, the patterned blackening layers 241 and 242 are illustrated, which are arrange on the top parts of the respective electrically conductive substrates 201 and 202. The patterned copper layers 231 and 232 are respectively in the same patterns as the patterned blackening layers 241 and 242, so that the patterned copper layers 231 and 232 are in a mesh shape, similar to the patterned blackening layers 241 and 242. Furthermore, the patterned adhesive layers 221 and 222 may be in a mesh shape, similar to the patterned blackening layers 241 and 242.

The method of adhering the laminated two plates of the electrically conductive substrates is not particularly limited, and, for example, they can be adhered and secured by using an adhesive, etc.

As described above, by laminating the one electrically conductive substrate 201 and the other electrically conductive substrate 202, the laminated electrically conductive substrate 30 provided with the mesh-shaped wiring can be obtained, as illustrated in FIG. 3A.

Note that, in FIG. 3A and FIG. 3B, an example is illustrated in which the mesh-shaped wiring (wiring pattern) is formed by combining the line-shaped wirings; however, it is not limited to the embodiment, and the wiring forming the wiring pattern may have any shape. For example, the shapes of the wirings forming the mesh-shaped wiring pattern may be formed to be various shapes, such as a line bent in a zigzag pattern (zigzag line), so that a moire pattern (interference fringes) is not generated with the image on the display.

Here, it is described by using the example in which the laminated electrically conductive substrate provided with the mesh-shaped wiring is obtained by laminating the two plates of the electrically conductive substrate; however, the method of obtaining the (laminated) electrically conductive substrate provided with the mesh-shaped wiring is not limited to the embodiment. For example, the electrically conductive substrate provided with the mesh-shaped wiring may be obtained from the electrically conductive substrate 10B illustrated in FIG. 1B in which the copper layers 13A and 13B are respectively formed on the first principal plane 11a and the second principal plane 11b of the transparent base 11.

In this case, the adhesive layer 12A, the copper layer 13A, and the blackening layer 14A laminated at the side of the first principal plane 11a of the transparent base 11 are patterned into a plurality of line-shaped patterns parallel to the Y-axis direction in FIG. 1B, namely, the direction perpendicular to the paper surface.

Additionally, the adhesive layer 12B, the copper layer 13B, and the blackening layer 14B laminated at the side of the second principal plane lib of the transparent base 11 are patterned into a plurality of line-shaped patterns parallel to the X-axis direction in FIG. 1B. As described above, patterning can be performed, for example, by etching. As a result, similar to the electrically conductive substrate 40 illustrated in FIG. 4, the electrically conductive substrate provided with a mesh-shaped wiring can be obtained by the patterned copper layer 43A formed at the side of the first principal plane 11a of the transparent base and the patterned copper layer 43B formed at the side of the second principal plane 11b, which nip the transparent base 11. Furthermore, in the electrically conductive substrate 40 illustrated in FIG. 4, the patterned adhesive layer 42A and the patterned adhesive layer 42B, and the patterned blackening layer 44A and the patterned blackening layer 44B similarly have mesh shapes.

In the (laminated) electrically conductive substrate described above, the copper layer is provided with a property such that, when the film thickness is 0.5 μm, the surface resistance value is less than or equal to 0.07Ω/□. As a result, when a film thickness of the copper layer is selected so that the surface resistance value of the electrically conductive layer is within a predetermined range, the film thickness of the copper layer can be made small. Namely, even if the film thickness of the copper layer is made small, the surface resistance value of, the electrically conductive substrate can be controlled.

Furthermore, in addition to the fact that, as described above, the film thickness of the copper layer can be made small, the copper layer can be patterned so as to form a thin line. As a result, after the patterning, reflection of light on the surface of the copper layer, especially, on the side surface of the copper layer, can be suppressed.

(Method for Manufacturing the Electrically Conductive Substrate)

Next, a configuration example of a method for manufacturing an electrically conductive substrate according to the embodiment is described.

The method for manufacturing the electrically conductive substrate according to the embodiment may include the following process.

A copper layer forming process of forming a copper layer on at least one surface of a transparent base.

Here, as the copper layer formed in the copper layer forming process, a copper layer may be used such that, when a film thickness is 0.5 μm, a surface resistance value is less than or equal to 0.07Ω/□.

The method for manufacturing the electrically conductive substrate according to the embodiment is specifically described below.

Note that, by the method for manufacturing the electrically conductive substrate according to the embodiment, the above-described electrically conductive substrate can favorably be manufactured. Accordingly, except for the points described below, the descriptions are omitted because the configuration can be the same as that of the above-described electrically conductive substrate.

The transparent base provided to the copper layer forming process can be prepared in advance (transparent base preparation process). The type of the transparent base to be used is not particularly limited; however, as already described, a resin substrate (resin film) that transmits visible light, a glass substrate, etc., can preferably be used. Depending on necessity, the transparent base may be cut into any size, in advance.

(Copper Layer Forming Process)

Then, as already described, the copper layer may preferably be provided with a copper thin film layer. Furthermore, the copper layer may be provided with the copper thin film layer and a copper plating layer. Accordingly, the copper layer forming process may include, for example, a process of forming the copper thin film layer by a dry plating method. Further, the copper layer forming process may include the process of forming the copper thin film layer by the dry plating method and a process of forming the copper plating layer on the copper thin film layer.

The dry plating method used for the process of forming the copper thin film layer is not particularly limited; for example, a vapor deposition method, a sputtering method, an ion plating method, etc., may be used. Note that, as the vapor deposition method, a vacuum deposition method can preferably be used. As the dry plating method used for the process of forming the copper thin film layer, the sputtering method may more preferably be used because, in particular, the film thickness can be easily controlled.

Next, the process of forming the copper plating layer is described. A condition in the process of forming the copper plating layer by a wet plating method is not particularly limited; various conditions may freely adopted so that the surface resistance value is within a predetermined range. For example, the copper plating layer can be formed by placing a base on which the copper thin film layer is formed in a plating tank filled with a copper plating solution, and by controlling electric current density and conveyance speed of the base.

However, as already described, in the process of forming the copper plating layer, the film of the copper plating layer may preferably be formed by a wet method using a single plating tank.

Further, in the process of forming the copper plating layer, the film of the copper plating layer may preferably be formed by an electroplating method, and, as an additive to the copper plating solution, a diallyldimethylammonium chloride polymer may preferably be used.

In particular, in the process of forming the copper plating layer, the film of the copper plating layer may preferably be formed by the electroplating method using the single plating tank, and, as the additive to the copper plating solution, the diallyldimethylammonium chloride polymer may preferably be used.

Note that, when the diallyldimethylammonium chloride polymer is added to the copper plating solution as the additive, the addition amount is not particularly limited, and it can be freely selected. For example, it can be added so that the addition amount of the diallyldimethylammonium chloride polymer in the copper plating solution is greater than or equal to 5 mg/L and less than or equal to 40 mg/L.

The molecular weight of the diallylammonium chloride polymer may preferably be in a range from 3500 to 4500. The reason is that, when the molecular weight is less than 3500, copper crystal growth may not be sufficiently progressed in the copper layer, and when it exceeds 4500, it may not sufficiently contribute to the growth of the copper crystals.

The diallyldimethylammonium polymer may be a single polymer; however, it is particularly desirable for promoting crystal growth of copper to use a diallyldimethylammonium-SO₂ copolymer, as the diallyldimethylammonium polymer.

As already described, the electrically conductive substrate may be provided with the blackening layer and/or the adhesive layer. Consequently, a blacken layer forming process and/or an adhesive layer forming process may further be included.

(Blackening Layer Forming Process)

The blackening layer forming process is described. In the blackening layer forming process, a method for forming the blackening process is not particularly limited, and it can be formed by any method.

For forming the blackening layer in the blackening layer forming process, for example, a dry plating method, such as a sputtering method, an ion plating method, and an evaporation method, may preferably be used. In particular, the sputtering method may more preferably be used because the film thickness can be easily controlled.

Further, as already described, the film of the blackening layer may be formed by a wet method, such as an electroplating method.

(Adhesive Layer Forming Process)

Next, an adhesive layer forming process is described. When the adhesive layer forming process is to be performed, the copper layer forming process may be performed after the adhesive layer forming process.

For example, in FIG. 1A, the adhesive layer may be formed on the first principal plane 11a, which is one of the principal planes of the transparent base 11. Further, for the electrically conductive substrate 10B illustrated in FIG. 1B, the adhesive layers may be respectively formed on the first principal plane 11a and the second principal plane 11b of the transparent base 11. When the adhesive layers are respectively formed on the first principal plane 11a and the second principal plane 11b of the transparent base 11, the adhesive layers may be simultaneously formed on both the principal planes. Alternatively, the adhesive layer may be formed on one of the principal planes, and then the adhesive layer may be formed on the other principal plane.

The material forming the adhesive layer is not particularly limited. It can be freely selected depending on the degree of adhesion between the transparent base and the copper layer and the degree of suppression of reflection of light on the surface of the copper layer, and the degree of stability with respect to the environment (e.g., humidity and temperature) in which the electrically conductive substrate is used. Materials that can be favorably used as a material forming the adhesive layer are already described. Accordingly, the description is omitted here.

The film formation method of the adhesive layer is not particularly limited; however, as described above, the film may be formed by a dry plating method. As the dry plating method, for example, a sputtering method, an ion plating method, a vapor deposition method, etc., may preferably be used. When the film of the adhesive layer is formed by the dry method, the sputtering method may more preferably used because the film thickness can be easily controlled. Note that, as described above, one or more elements selected from carbon, oxygen, hydrogen, and nitrogen may be added to the adhesive layer, and, in this case, a reactive sputtering method can more preferably be used.

Note that, when the adhesive layer is to include one or more elements selected from carbon, oxygen, hydrogen, and nitrogen, these can be added to inside the adhesive layer by adding a gas including the one or more elements selected from carbon, oxygen, hydrogen, and nitrogen to the atmosphere for forming the film of the adhesive layer. For example, when carbon is to be added to the adhesive layer, carbon monoxide gas and/or carbon dioxide gas may be added to the atmosphere for performing the dry plating; when oxygen is to be added, oxygen gas may be added to the atmosphere for performing the dry plating; when hydrogen is to be added, hydrogen gas and/or water may be added to the atmosphere for performing the dry plating; and when nitrogen is to be added, nitrogen gas may be added to the atmosphere for performing the dry plating.

The gas including the one or more elements selected from carbon, oxygen, hydrogen, and nitrogen may preferably be added to an inert gas to be used as an atmosphere gas during the dry plating. The inert gas is not particularly limited; however, for example, argon can preferably be used.

When the film of the adhesive layer is to be formed by the reactive sputtering method, as the target, a target including the types of metals forming the adhesive layer may be used. When the adhesive layer includes an alloy, for each of the types of the metals included in the adhesive layer, a target may be used to form the alloy on the surface of a film formation target, such as a substrate, or a target may be used in which the metals included in the adhesive layer are alloyed in advance.

As described above, by forming the film of the adhesive layer by the dry plating method, the adhesion between the transparent base and the adhesive layer can be enhanced. Further, as the adhesive layer may include, for example, a metal, as a main component, it has high adhesion to the copper layer. Consequently, by placing the adhesive layer between the transparent base and the copper layer, peeling off of the copper layer can be suppressed.

(Patterning Process)

The electrically conductive substrate obtained by the method of manufacturing the electrically conductive substrate according to the embodiment can be used for various applications, such as a touch panel. Then, when it is used for various applications, the copper layer included in the electrically conductive substrate according to the embodiment may preferably be patterned. Note that, when the blackening layer and the adhesive layer are formed, the blackening layer and the adhesive layer may preferably be patterned. The copper layer, and, additionally, the blackening layer and the adhesive layer, depending on a case, can be patterned for example, according to a desired wiring pattern; and the copper layer, and, additionally, the blackening layer and the adhesive layer, depending on a case, may preferably be patterned in the same shapes.

Accordingly, the method of manufacturing the electrically conductive substrate according to the embodiment may include a patterning process for patterning the copper layer. Note that, when the blackening layer and the adhesive layer are formed, the patterning process may be a process for patterning the adhesive layer, the copper layer, and the blackening layer.

The specific procedure of the patterning process is not particularly limited, and it can be performed by any procedure. For example, when, in the electrically conductive substrate 10A, the adhesive layer 12, the copper layer 13, and the blackening layer 14 are laminated on the transparent base 11, as in FIG. 1A, first, a mask placing process for placing a mask with a desired pattern on the blackening layer 14 can be performed. Next, an etching process can be performed, which is for supplying an etchant on the upper surface of the blackening layer 14, i.e., the side of the surface on which the mask is placed.

The etchant used in the etching process is not particularly limited, and it can be freely selected depending on the material forming the layer to be etched. For example, the etchant may be changed for each layer, or the copper layer, and additionally the blackening layer and the adhesive layer, depending on a case, may be simultaneously etched by the same etchant.

Further, as in FIG. 1B, a patterning process may be performed for patterning the electrically conductive substrate 10B such that the adhesive layer 12A, the cupper layer 13A, and the blackening layer 14A are laminated on the first principal plane 11a of the transparent base 11, and the adhesive layer 12B, the cupper layer 13B, and the blackening layer 14B are laminated on the second principal plane 11b of the transparent base 11. In this case, for example, a mask placing process can be performed, which is for placing masks with desired patterns on the blackening layers 14A and 14B. Subsequently, an etching process can be performed, which is for supplying an etchant on the upper surfaces of the blackening layers 14A and 14B, namely, the sides of the surfaces on which the masks are placed.

The pattern formed by the etching process is not particularly limited, and it can have any shape. For example, for the electrically conductive substrate 10A illustrated in FIG. 1A, as already described, patterns may be formed for the adhesive layer 12, the copper layer 13, and the blackening layer 14 so as to include a plurality of lines or a line bent in a zigzag pattern (zigzag line), etc.

Further, for the electrically conductive substrate 10B illustrated in 1B, a pattern can be formed so as to form a mesh-shaped wiring by the copper layer 13A and the copper layer 13B. In this case, the adhesive layer 12A and the blackening layer 14A may preferably be patterned so as to have the same shapes as that of the copper layer 13A, and the adhesive layer 12B and the blackening layer 14B may preferably be patterned so as to have the same shapes as that of the copper layer 13B.

Furthermore, for example, after the copper layer 13, etc., is patterned in the patterning process for the above-described electrically conductive substrate 10A, a lamination process may be performed, in which two or more plates of patterned electrically conductive substrates are laminated. During lamination, for example, by laminating the electrically conductive substrates so that the patterns of the copper layers intersect each other, a laminated electrically conductive substrate provided with a mesh-shaped wiring can be obtained.

A method of securing the two or more laminated electrically conductive substrate is not particularly limited; however, for example, they can be secured by an adhesive, etc.

When an electrically conductive substrate is manufactured by the method of manufacturing the electrically conductive substrate according to the embodiment, which is described above, a copper layer can have a property such that, when the film thickness is 0.5 μm, the surface resistance value is less than or equal to 0.07Ω/□. As a result, when a film thickness of the copper layer is selected so that the surface resistance value of the electrically conductive layer is within a predetermined range, the film thickness of the copper layer can be made small. Namely, even if the film thickness of the copper layer is made small, the surface resistance value of the electrically conductive substrate can be controlled.

Furthermore, in addition to that the film thickness of the copper layer can be made small, as described above, the copper layer can be patterned so as to form a thin line. As a result, after the patterning, reflection of light on the surface of the copper layer, especially, on the side surface of the copper layer, can be suppressed.

### EXAMPLES

In the following, specific examples and a reference example are described; however, the present invention is not limited to these examples.

### Example 1

(Preliminary Test)

First, as a preliminary test, an evaluation sample, in which a thickness of a copper layer was from 0.1 μm to 0.5 μm, was produced, which was an electrically conductive substrate such that a film of a copper layer including a copper thin film layer and a copper plating layer was formed on a transparent base. A surface resistance value of the evaluation sample was evaluated. In the following, a procedure for producing the evaluation sample is described.

A transparent base formed of a polyethylene terephthalate resin (PET) having a length of 500 mm×a width of 500 mm and a thickness of 50 μm was prepared. Here, when the total light transmittance of the transparent base formed of the polyethylene terephthalate resin, which was used as the transparent base, was evaluated by the method specified by JIS K 7361-1, the total light transmittance was 97%.

In the copper layer forming process, a copper thin film forming process and a copper plating layer forming process were performed.

First, the copper thin film forming process is described.

In the copper thin film forming process, the above-described transparent base formed of the polyethylene terephthalate resin was used as a base, and a copper thin film layer was formed on the transparent base under the following conditions.

The above-described transparent base was heated, in advance, up to 60° C. to remove moisture, and it was placed inside a chamber of a sputtering device to which a copper target was attached.

Next, after evacuating inside the chamber to 1×10⁻³ Pa, argon gas was introduced, and the pressure inside the chamber was adjusted to be 1.3 Pa.

Then, under such an atmosphere, electric power was supplied to the target, and a film of the copper layer was formed on one of the principal planes of the transparent base, so that the thickness was 50 nm.

Next, in the copper plating layer forming process, the copper plating layer was formed on the copper thin film layer. The film of the copper plating layer was formed by an electroplating method, and each evaluation sample was formed so that the thickness of the film of the copper layer was from 0.1 μm to 0.5 μm, as illustrated in Table 1.

In the preliminary test of Example 1, a single plating tank was used for forming the copper plating layer, and a copper plating solution to which a diallyldimethyl ammonium chloride-SO₂ copolymer was added was used as a plating solution.

As the plating solution used in the copper plating layer forming process, a copper plating solution was used which was prepared so that the concentrations of copper, sulfuric acid, and chlorine were copper 30 g/L; sulfuric acid 80 g/L; and chlorine 50 mg/L. The above-described DDAC-S₂ copolymer (diallyldimethyl ammonium chloride-SO₂ copolymer) was added, as an additive, to be 20 mg/L to the used copper plating solution. Furthermore, in addition to the DDAC-SO₂ copolymer, 650 mg/L PEG (polyethylene glycol), as a polymer component, and 15 mg/L SPS (bis (3-sulfopropyl) disulfide), as a brightener component, were added to the plating solution.

For the obtained evaluation sample, the surface resistance value was evaluated.

The surface resistance value was measured using a low resistivity meter (manufactured by Dia Instruments Ltd., Model: Loresta EP MCP-T360). The measurement was performed by the four-probe method. The measurement was performed in which the probes contact the outermost layer of the sample, namely, the copper layer in this preliminary test.

The evaluation results are shown in Table 1 and FIG. 5.

According to the results shown in Table 1 and FIG. 5, it was confirmed that, when the thickness of the copper layer was 0.5 μm, the surface resistance value was less than or equal to 0.07Ω/□.

(Production of the Electrically Conductive Substrate)

Then, an electrically conductive substrate was produced under the conditions that were the same as those of the preliminary test, except that the thickness of the copper layer was adjusted to be 0.5 μm and that a blackening layer was further formed on the copper layer.

First, as the copper layer forming process, a copper layer was formed on the transparent base similar to the case of the preliminary test, except that the thickness of the copper layer was adjusted to be 0.5 μm, as described above. The description of the conditions on the production is omitted.

In the blackening layer forming process, an Ni—Cu layer including oxygen was formed, as the blackening layer, on the copper layer by the sputtering method.

In the blackening layer forming process, by a sputtering device in which a Ni-35 wt % Cu alloy target was attached, a film of the Ni—Cu alloy layer including oxygen was formed as the blackening layer. In the following, a procedure of forming the film of the blackening layer is described.

First, a laminated body obtained by laminating the copper layer on the transparent base was set inside a chamber of the sputtering device.

Next, after evacuating inside the chamber to 1×10⁻³ Pa, argon gas and oxygen gas were introduced, and the pressure inside the chamber was adjusted to be 1.3 Pa. Note that, at this time, the atmosphere inside the chamber was such that, in volume ratio, 30% was oxygen and the remainder was argon.

Then, under such an atmosphere, electric power was supplied to the target, and film of the blackening was formed on the copper layer so that the thickness was 30 nm.

By the above-described process, the blackening layer was formed on the upper surface of the copper layer, namely, on the surface opposite to the surface of the copper layer facing the transparent base, and the electrically conductive substrate was obtained such that the copper layer and the blackening layer were laminated on the transparent substrate in this order.

By measuring the surface resistance value of the obtained electrically conductive substrate similar to the case of the preliminary test, it was confirmed that the surface resistance value was 0.037Ω/□. This is the same as the result of a case where the thickness of the copper layer was 0.5 μm. The reason is that the thickness of the blackening layer was as thin as 30 nm so that almost no effect was provided on the surface resistance value of the electrically conductive substrate.

### Example 2

(Preliminary Test)

The evaluation sample was produced similar to the preliminary test of Example 1, except that, in the copper plating layer forming process, five plating tanks were used, and that the film of the copper plating layer was formed so that the thickness of the copper layer was adjusted to be from 0.2 μm to 0.5 μm, as shown in Table 1.

Note that, similar to the case of Example 1, a diallyldimethyl ammonium chloride-SO₂ copolymer was added to the copper plating solution used for the copper plating layer forming process.

Similar to Example 1, the surface resistance value was evaluated for the obtained evaluation sample.

The evaluation results are shown in Table 1 and FIG. 5.

According to the results shown in Table 1 and FIG. 5, it was confirmed that, when the thickness of the copper layer was 0.5 μm, the surface resistance value was less than or equal to 0.07Ω/□.

(Production of the Electrically Conductive Substrate)

Then, an electrically conductive substrate was produced under the conditions that were the same as those of the preliminary test, except that the thickness of the copper layer was adjusted to be 0.5 μm and that a blackening layer was further formed on the copper layer.

The blackening layer was produced under the conditions that were the same as those of Example 1.

By measuring the surface resistance value of the obtained electrically conductive substrate similar to the case of the preliminary test, it was confirmed that the surface resistance value was 0.055Ω/□. This is the same as the result of a case where the thickness of the copper layer was 0.5 μm. The reason is that the thickness of the blackening layer was as thin as 30 nm so that almost no effect was provided on the surface resistance value of the electrically conductive substrate.

### Example 3

(Preliminary Test)

An Evaluation sample was produced similar to the preliminary test of Example 1, except that, instead of the DDAC-SO₂ copolymer, Janus Green B was used as an additive to the copper plating solution in the copper plating layer forming process, and that the copper plating layer was formed so that the thickness of the copper layer was adjusted to be from 0.2 μm to 0.5 μm, as illustrated in Table 1.

Note that, as the copper plating solution used for the copper plating layer forming process, instead of the DDAC-SO₂ copolymer added to the plating solution described in Example 1, Janus Green B added to have the same concentration was used, and no DDAC-SO₂ copolymer was included. Further, in the copper plating layer forming process, a single plating tank was used.

Similar to Example 1, the surface resistance value was evaluated for the obtained evaluation sample.

The evaluation results are shown in Table 1 and

FIG. 5.

According to the results shown in Table 1 and FIG. 5, it was confirmed that, when the thickness of the copper layer was 0.5 μm, the surface resistance value was less than or equal to 0.07Ω/□.

(Production of the Electrically Conductive Substrate)

Then, an electrically conductive substrate was produced under the conditions that were the same as those of the preliminary test, except that the thickness of the copper layer was adjusted to be 0.5 μm and that a blackening layer was further formed on the copper layer.

The blackening layer was produced under the conditions that were the same as those of Example 1.

By measuring the surface resistance value of the obtained electrically conductive substrate similar to the case of the preliminary test, it was confirmed that the surface resistance value was 0.05Ω/□. This is the same as the result of a case where the thickness of the copper layer was 0.5 μm. The reason is that the thickness of the blackening layer was as thin as 30 nm so that almost no effect was provided on the surface resistance value of the electrically conductive substrate.

### Reference Example

(Preliminary Test)

An Evaluation sample was produced similar to Example 1, except that Janus Green B was used as an additive to the copper plating solution in the copper plating layer forming process, that five plating tanks were used, and that the film of the copper plating layer was formed so that the thickness of the copper layer was adjusted to be from 0.2 μm to 0.5 μm, as illustrated in Table 1.

Note that, as the copper plating solution used for the copper plating layer forming process, instead of the DDAC-SO₂ copolymer added to the plating solution described in Example 1, Janus Green B added to have the same concentration was used, and no DDAC-SO₂ copolymer was included.

Similar to Example 1, the surface resistance value was evaluated for the obtained evaluation sample. The evaluation results are shown in Table 1 and FIG. 5.

According to the results shown in Table 1 and FIG. 5, it was confirmed that, when the thickness of the copper layer was 0.5 μm, the surface resistance value exceeded 0.07Ω/□.

(Production of the Electrically Conductive Substrate)

Then, an electrically conductive substrate was produced under the conditions that were the same as those of the preliminary test, except that the thickness of the copper layer was adjusted to be 0.5 μm and that a blackening layer was further formed on the copper layer.

The blackening layer was produced under the conditions that were the same as those of Example 1.

By measuring the surface resistance value of the obtained electrically conductive substrate similar to the case of the preliminary test, it was confirmed that the surface resistance value was 0.072Ω/□, which was greater compared to Example 1 through Example 3.

Namely, it was confirmed that, in order to obtain a desired surface resistance value in the electrically conductive substrate produced in Reference Example 1, the thickness of the copper layer is required to be made greater than those of Example 1 through Example 3. Then, as the thickness of the copper layer increases, reflection on the copper layer, especially on the side surface of the copper layer, tends to occur. Consequently, it is confirmed, when it is used, for example, for a touch panel, visibility of the display is lowered compared to the electrically conductive substrate according to Example 1 through Example 3.

TABLE 1

| | |
|---|---|
| Thickness | Surface resistance (Ω/□) |

| of copper | | | | Reference |
|---|---|---|---|---|
| layer (μm) | Example 1 | Example 2 | Example 3 | Example 1 |
| 0.1 | 0.16 | — | — | — |
| 0.15 | 0.1 | — | — | — |
| 0.2 | 0.078 | 0.11 | 0.1 | 0.13 |
| 0.25 | 0.065 | 0.09 | 0.085 | 0.106 |
| 0.3 | 0.055 | 0.08 | 0.075 | 0.096 |
| 0.35 | 0.049 | 0.07 | 0.068 | 0.086 |
| 0.4 | 0.044 | 0.065 | 0.06 | 0.008 |
| 0.45 | 0.04 | 0.06 | 0.055 | 0.076 |
| 0.5 | 0.037 | 0.055 | 0.05 | 0.072 |

The electrically conductive substrate is described above by the embodiment and the examples, etc.; however, the present invention is not limited to the above-described embodiment and examples, etc. Various modifications and alterations can be made within the scope of the gist of the present invention described in the claims.

The present application is based on and claims the benefit of priority of Japanese Priority Application No. 2015-129285 filed on Jun. 26, 2015, the entire contents of Japanese Priority Application No. 2015-129285 are hereby incorporated by reference.

### LIST OF REFERENCE SYMBOLS

10A, 10B, 20, 201, 202, 40: electrically conductive substrate

11: transparent base

13, 13A, 13B, 23, 231, 232, 43A, 43B: copper layer

1. An electrically conductive substrate comprising:
a transparent base; and
a copper layer formed on at least one surface of the transparent base,
wherein the copper layer is such that, when a film thickness of the copper layer is 0.5 a surface resistance value is less than or equal to 0.07Ω/□.

2. The electrically conductive substrate according to claim 1, wherein the copper layer includes a copper plating layer formed by a wet method, and
wherein the copper plating layer is formed using a single plating tank.

3. The electrically conductive substrate according to claim 1, wherein the copper layer includes a copper plating layer formed by an electroplating method, and
wherein, when the copper plating layer is to be formed, a diallyldimethylammonium chloride polymer is used as an additive.

4. The electrically conductive substrate according to claim 3, wherein a diallyldimethylammonium chloride-SO₂ copolymer is used as the diallyldimethylammonium chloride polymer.

5. The electrically conductive substrate according to claim 2, wherein the copper layer includes a copper plating layer formed by an electroplating method, and
wherein, when the copper plating layer is to be formed, a diallyldimethylammonium chloride polymer is used as an additive.

6. The electrically conductive substrate according to claim 5, wherein a diallyldimethylammonium chloride-SO₂ copolymer is used as the diallyldimethylammonium chloride polymer.
